(19) United States
(12) Patent Application Publication
(10) Pub. No.: US 2011/0203831 A1
(43) Pub. Date: Aug. 25, 2011

(54) METAL/CNT AND/OR FULLERENE COMPOSITE COATING ON STRIP MATERIALS

(75) Inventors: Helge Schmidt, Speyer (DE); Isabell Buresch, Illertissen (DE); Udo Adler, Koblenz (DE); Dirk Rode, Osnabruck (DE); Sonja Priggemeyer, Wallenhorst (DE)

(73) Assignee: KME GERMANY AG & CO.KG

(21) Appl. No.: 13/125,195

(22) PCT Filed: Sep. 3, 2009
(86) PCT No.: PCT/DE09/01236

§ 371 Date: Apr. 20, 2011

(30) Foreign Application Priority Data
Oct. 24, 2008 (DE) 10 2008 053 030.1

(51) Int. Cl. B32B 15/04; B01D 9/00; C23C 16/26; C23C 16/44; B05D 1/36; C25D 7/06; H01B 5/00; B82Y 30/00; B82Y 40/00

(52) U.S. Cl. 174/126.2; 428/615; 428/655; 428/593; 427/249.1; 205/152; 977/734; 977/742; 977/842

(57) ABSTRACT

A composite coating on metal strips or prestamped metal strips with an improved friction coefficient and/or good contact resistance and/or good friction corrosion resistance and/or good wear resistance and/or good formability includes carbon nanotubes and/or fullerenes and a metal. A method for producing a metal strip coated according to the invention with carbon nanotubes and/or fullerenes and a metal is also disclosed.

The invention relates to metal/carbon nanotubes (CNT) and/or a fullerene composite coating on metal strips, which has an improved friction value, good contact resistance, good friction corrosion resistance, good wear resistance and good formability. The invention also relates to a method for producing a metal strip coated according to the invention.

Carbon nanotubes (CNTs) were discovered by Sumio Iijama in 1991 (see S. Iijama, Nature, 1991, 354, 56). Iijama discovered in the soot of a fullerene generator under certain reaction conditions tube-like structures with a diameter of only several 10 nm, but with a length of several micrometers. The discovered compounds consisted of several concentric graphite tubes which acquired the designation multi-wall carbon nanotubes (MWCNTs). Shortly thereafter, single-wall CNTs with a diameter of only approximately 1 nm were discovered by Iijama and Ichihashi, which were designated accordingly as single-wall carbon nanotubes (SWCNTs) (see S. Iijama, T. Ichihashi, Nature, 1993, 363, 6430).

Several outstanding properties of CNTs are, for example, their mechanical tensile strength and stiffness of about 40 GPa and 1 TPa, respectively (20 times and 5 times greater than that of steel).

CNTs exist as both conducting and semiconducting materials. The carbon nanotubes are part of the family of fullerenes and have a diameter of 1 nm to several 100 nm. Carbon nanotubes are microscopically small tubular structures (molecular nanotubes) made of carbon. Their walls consist, like those of fullerenes or like the planes of graphite, only of carbon, whereby the carbon atoms have a honeycomb-like structure with six corners, with each carbon atom having three binding partners (determined by the sp²-hybridization). The diameter of the tubes is mostly in a range between 1 and 50 nm, whereby tubes with only 0.4 nm diameter have also been produced. Lengths of several millimeters for individual tubes and of up to 20 cm for tube bundles have already been achieved.

The synthesis of the carbon nanotubes occurs typically through precipitation of carbon from the gas phase or from a plasma. In particular, the current-carrying capacity and the thermal conductivity are of interest to the electronics industry. The current-carrying capacity is approximately 1000 times greater than that of copper wires, the thermal conductivity at room temperature is with 6000 W/m*K approximately twice that of diamond, the best naturally occurring thermal conductor.

As already mentioned above, the carbon nanotubes belong to the group of the fullerenes. Spherical molecules of carbon atoms with a high symmetry are referred to as fullerenes which represent the third elemental modification of carbon (in addition to diamond and graphite). The fullerenes are typically produced by evaporating graphite under reduced pressure and in an inert gas atmosphere (e.g. argon) using resistance heating or in an electric arc. The aforedescribed carbon nanotubes are frequently produced as a byproduct. Fullerenes have from semiconducting to superconducting properties.

It is known in the art to mix carbon nanotubes with conventional plastic. The mechanical properties of the plastic material are thereby significantly improved. In addition, electrically conducting plastics can be produced; for example, nanotubes have already been used for rendering antistatic foils conductive.

Conventionally manufactured electromechanical components, for example plug connectors, switches, relay springs, directly pluggable lead frames and the like have a tin or silver or nickel coating. Problems resulting from a poor friction value and/or contact resistance, low wear resistance and/or poor formability are frequently observed. The use of carbon nanotubes and/or fullerenes for improving these properties is not known to date in the state-of-the-art.

It was therefore an object of the present invention to provide an electromechanical component which overcomes the aforementioned disadvantages, i.e., which has an improved friction value and/or a good contact resistance and/or good wear resistance and/or good formability.

The object is attained with a metal strip which includes a coating made from carbon nanotubes and/or fullerenes and metal.

A metal strip in the context of the present invention is preferably to be understood as a metal strip or an electromechanical component that is preferably made from copper and/or copper alloys, aluminum and/or aluminum alloys, or iron and/or iron alloys.

Preferably, the metal strip includes a diffusion barrier layer which is advantageously deposited on both sides of the metal strip. The metal strip should not be an insulator. Preferably, the diffusion barrier layer therefore includes a transition metal or consists of a transition metal. Preferred transition metals are, for example, Mo, B, Co, Fe/Ni, Cr, Ti, W or Ce.

The carbon nanotubes are arranged on the metal strip with a columnar structure, which can be achieved with the method according to the invention described below. The carbon nanotubes may be single-wall or multi-wall carbon nanotubes, which can also be controlled by the method according to the invention. The fullerenes are preferably arranged on the metal strip in form of spheres.

Preferably, the coating may also include graphene.

Graphenes refer to monatomic layers of sp²-hybridized carbon atoms. Graphenes have very high electrical and thermal conductivity along their plane. Graphenes are prepared by separating graphite into its basal planes. Initially, oxygen is intercalated. The oxygen partially reacts with the carbon and causes mutual repulsion of the layers. The graphenes are then suspended and embedded, depending on the application, for example in polymers, or as in the present invention used as a coating component for a metal strip.

Another possibility for preparing individual graphene layers involves heating hexagonal silicon carbide surfaces to temperatures above 1400° C. Due to the higher vapor pressure of silicon, the silicon atoms evaporate faster than the carbon atoms. Thin layers of single-crystalline graphite consisting of several graphene monolayers are then formed on the surface.

In a preferred embodiment, the graphenes and/or carbon nanotubes and/or fullerenes form a composite. In other words, the graphenes with carbon nanotubes, the graphenes with fullerenes, the fullerenes with carbon nanotubes or all components in conjunction can form a composite. In a particularly preferred embodiment, the graphenes are arranged orthogonally on the carbon nanotubes and/or fullerenes, wherein they represent for example the termination of a tube in the axial direction, or the graphenes or fullerenes are arranged orthogonally on the carbon nanotubes. An orthogonal arrangement of graphenes on the fullerenes represents quasi a tangential arrangement of the graphenes on the fullerenes. An orthogonal arrangement of the fullerenes on carbon nanotubes can be viewed as a scepter, wherein the fullerenes are located on one end of a carbon nanotube.

The metal strip has preferably a thickness from 0.06 to 3 mm, particularly preferred from 0.08 to 2.7 mm.

The object of the invention is also a method for preparing a metal strip coated with carbon nanotubes and/or fullerenes and a metal, including the steps of

a) coating a metal strip with a diffusion barrier layer,

b) depositing a nucleation layer on the diffusion barrier layer,

c) exposing the metal strip treated according to step a) and b) to an atmosphere containing organic, gaseous compounds,

d) forming carbon nanotubes and/or fullerenes on the metal strip at a temperature from 200° C. to 1500° C.,

e) permeating the carbon nanotubes and/or fullerenes with a metal.

In the method of the invention, the metal strip is preferably coated on both sides with a diffusion barrier layer. Advantageously, a nucleation layer is deposited on the diffusion barrier layer, which supports columnar growth of the carbon nanotubes and/or precipitation of fullerenes. The nucleation layer used in this method preferably includes a metal salt, selected from metals of the Fe-group, the 8^{th}, 9^{th} and 10^{th} secondary groups of the periodic system of the elements.

The metal strip treated in this manner is subsequently exposed to an atmosphere which is preferably a hydrocarbon atmosphere. Particularly preferred is the hydrocarbon atmosphere of a methane atmosphere, whereby a carrier gas can also be added to the atmosphere or the hydrocarbon atmosphere. For example, a carrier gas may be argon.

Carbon nanotubes and/or fullerenes are typically formed on the metal strip at a temperature from 200° C. to 1500° C. At a temperature from 200° C. to 900° C. preferably multi-wall carbon nanotubes (MWCNTs) are formed. At a temperature greater than 900° C. to about 1500° C. preferably single-wall carbon nanotubes (SWCNTs) are formed. The quality of the carbon nanotubes can be improved when growth takes place in a moist atmosphere. The carbon nanotubes on the metal strip are formed with a columnar structure, which is supported by the nucleation layer. The fullerenes precipitate on the metal strip preferably in the form of spheres.

Thereafter, the carbon nanotubes and/or the fullerenes are permeated with a metal. Suitable metals are the metals Sn, Ni, Ag, Au Pd, Cu or W and their alloys already mentioned above.

Permeation of the carbon nanotubes and/or fullerenes with the metal is preferably performed with a vacuum process, for example CVD (chemical vapor deposition) or PVD (physical vapor deposition), electrolytically, electroless reductive, or by melting/infiltration.

Preferably, graphenes are also introduced into the coating. Preferably, the graphenes and/or carbon nanotubes and/or fullerenes form a composite. In other words, the graphenes together with the carbon nanotubes, the graphenes together with the fullerenes, the fullerenes with the carbon nanotubes or all three components in combination may form a composite. In a particularly preferred embodiment, the graphenes are arranged orthogonally on the carbon nanotubes and/or fullerenes, whereby they represent for example the termination of a tube in the axial direction, or the graphenes or fullerenes are arranged orthogonally on the carbon nanotubes. An orthogonal arrangement of graphenes on fullerenes represents quasi a tangential arrangement of the graphenes on the fullerenes. An orthogonal arrangement of the fullerenes on carbon nanotubes can be viewed as a scepter, wherein the fullerene is located on one end of a carbon nanotube.

A metal strip produced in this way and coated with metal and carbon nanotubes and/or fullerenes (and graphenes) is distinguished by an improved friction value, good contact resistance, good wear resistance and good formability and is therefore superbly suited as an electromechanical component, for example for plug connectors, switches, relays springs or the like. In particular, in combination with graphenes in form of the aforedescribed composite, an electrical and thermal conductivity in the horizontal and vertical direction can be provided, which is particularly advantageous.

What is claimed is:

1.-29. (canceled)

30. A metal strip, comprising a coating of carbon nanotubes and/or fullerenes, and a metal.

31. The metal strip of claim 30, further comprising a diffusion barrier layer deposited on both sides of the metal strip.

32. The metal strip of claim 31, wherein the diffusion barrier layer is not electrically insulating.

33. The metal strip of claim 31, wherein the diffusion barrier layer comprises a transition metal.

34. The metal strip of claim 30, wherein the metal of the coating is selected from the group consisting of Sn, Ni, Ag, Au Pd, Cu or W and their alloys.

35. The metal strip of claim 30, wherein the carbon nanotubes are arranged on the metal strip in form of columns.

36. The metal strip of claim 30, wherein the carbon nanotubes are single-wall or multi-wall carbon nanotubes.

37. The metal strip of claim 30, wherein the metal strip has a thickness from 0.06 mm to 3 mm.

38. The metal strip of claim 30, wherein the coating further comprises graphenes.

39. The metal strip of claim 38, wherein a combination of at least two of the graphenes, the carbon nanotubes and the fullerenes forms a composite.

40. The metal strip of claim 38, wherein the graphenes or fullerenes, or both, are arranged orthogonally on the carbon nanotubes, or wherein the graphenes are arranged orthogonally on the carbon nanotubes or the fullerenes, or both.

41. The metal strip of claim 30, wherein the metal strip is prestamped.

42. A method for producing a metal strip coated with carbon nanotubes and/or fullerenes and a metal, comprising the steps of:
a) coating the metal strip with a diffusion barrier layer,
b) depositing a nucleation layer on the diffusion barrier layer,
c) exposing the metal strip treated according to step a) and b) to an atmosphere containing organic, gaseous compounds,
d) forming carbon nanotubes and/or fullerenes on the metal strip at a temperature from 200° C. to 1500° C.,
e) permeating the carbon nanotubes and/or fullerenes with the metal.

43. The method of claim 42, wherein the metal strip is coated on both sides with the diffusion barrier layer.

44. The method of claim 42, wherein the nucleation layer comprises a metal salt having at least one metal constituent selected from the Fe-group and the 8^{th}, 9^{th} and 10^{th} secondary groups of the periodic system of the elements.

45. The method of claims 42, wherein the nucleation layer comprises a partial coating.

46. The method of claim 42, wherein the atmosphere containing organic, gaseous compounds comprises a hydrocarbon atmosphere.

47. The method of claim 46, wherein the atmosphere containing organic, gaseous compounds comprises a carrier gas in addition to the hydrocarbon atmosphere.

48. The method of claim 42, wherein the atmosphere containing organic gaseous compounds has a moisture content of 50-90%.

49. The method of claim 42, wherein carbon nanotubes and/or fullerenes are formed on the metal strip at a temperature from 200° C. to 900° C.

50. The method of claim 49, wherein the formed carbon nanotubes comprise multi-wall carbon nanotubes (MWCNTs).

51. The method of claim 42, wherein the temperature for forming the carbon nanotubes and/or the fullerenes is >900° C. to 1500° C.

52. The method of claim 51, wherein the formed carbon nanotubes comprise single-wall carbon nanotubes (SWCNTs).

53. The method of claim 42, wherein the carbon nanotubes are formed on the metal strip in form of columns.

54. The method of claim 42, wherein the carbon nanotubes and/or fullerenes are permeated with the metal by a process selected from a vacuum process, an electrolytic process, an electroless reductive process, and a melting/infiltration process.

55. The method of claim 42, and further comprising the step of introducing graphenes into the coating.

56. The method of claim 55, wherein the graphenes are arranged orthogonally on the carbon nanotubes and/or the fullerenes, or the graphenes and/or the fullerenes are arranged orthogonally on the carbon nanotubes.

57. The method of claim 55, wherein at least two of the graphenes, the carbon nanotubes and the fullerenes form a composite.

58. An electromechanical component or lead frame comprising a metal strip having a coating of carbon nanotubes and/or fullerenes, and a metal.
